(19) United States
(12) Patent Application Publication
(10) Pub. No.: US 2026/0247928 A1
(43) Pub. Date: Aug. 20, 2026

(54) IN-SITU TEST STRUCTURE AT WAFER SCRIBE LINE FOR PAD CORROSION MONITORING AND TESTING

(71) Applicant: Micron Technology, Inc., Boise, ID (US)

(72) Inventors: Chen-Yu HUANG, Taichung (TW); Chong Leong GAN, Taichung (TW)

(21) Appl. No.: 19/426,497

(22) Filed: Dec. 19, 2025

Related U.S. Application Data
(60) Provisional application No. 63/760,770, filed on Feb. 20, 2025.

(51) Int. Cl. H10P 74/00; G01N 17/00; G01N 17/04; H10P 74/20; H10W 20/00; H10W 20/20

(52) U.S. Cl. CPC H10P 74/273; G01N 17/006; G01N 17/04; H10P 74/203; H10P 74/207; H10W 20/021; H10W 20/20

(57) ABSTRACT

A method of manufacturing a wafer includes forming the wafer, including forming bond pads in a die region; forming test structures in a voltage divider configuration; and evaluating bond pad corrosion. The test structures include first, second, and third test pads formed on the wafer; an unexposed trace formed inside the wafer, wherein the unexposed trace, corresponding to a first leg of the voltage divider configuration, is coupled to the first test pad and the second test pad; and an exposed trace formed on the wafer, outside of the die region, wherein the exposed trace, corresponding to a second leg of the voltage divider configuration, is coupled to the second test pad and the third test pad. A comparison value of a resistance of the unexposed trace and a resistance of the exposed trace is associated with an amount of corrosion at the one or more bond pads.

### CROSS-REFERENCE TO RELATED APPLICATION

This Patent Application claims priority to U.S. Provisional Patent Application No. 63/760,770, filed on February 20, 2025, entitled “IN-SITU TEST STRUCTURE AT WAFER SCRIBE LINE FOR PAD CORROSION MONITORING AND TESTING,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to in-situ test structures on a wafer used for pad corrosion monitoring and testing.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 shows a wafer according to one or more implementations.

FIG. 2 shows a wafer according to one or more implementations.

FIG. 3 shows a schematic diagram of a corrosion test system according to one or more implementations.

FIG. 4 is a flowchart of an example method associated with an in-situ test structure at a wafer scribe line for pad corrosion monitoring and testing.

FIG. 5 is a flowchart of an example method of manufacturing a wafer assembly.

### DETAILED DESCRIPTION

Future development of advanced semiconductor packages may require higher density and higher integrated memory bandwidth (more power consumption) with smaller package form factors, smaller bond pads, and tighter pad pitches. Thus, not only will die densities on a wafer increase for increasing a number of dies produced from a wafer, but bond pads will become more difficult to test due to an increase in bond pad density and reduction in bond pad size and bond pad spacing. In particular, bond pads may be susceptible to corrosion, such as chemically-induced corrosion due to bond pad exposure to one or more chemicals used during wafer fabrication. For example, aluminum (Al) bond pads may be susceptible to pitting corrosion from being exposed to an acidic halide environment. Galvanic corrosion is another type of chemically-induced corrosion that may take place at aluminum bond pads due to a presence of bond balls, such a gold (Au) bond balls, copper (Cu) bond balls, silver (Ag) bond balls, palladium (Pd) bond balls, and alloys thereof (e.g., AuAg and PdCu), bonded to the bond pads. Galvanic corrosion is a chemical reaction, specifically an electrochemical reaction, that may occur between two dissimilar metals. Thus, the metal of the bond balls may act as a corrosive metal.

A chemically-induced corrosion of a bond pad may result in an undesirable increase in contact resistance at the bond pad. Thus, a bond pad with corrosion may have a higher resistance than a bond pad without corrosion. For example, a higher contact resistance may cause one or more electrical parameters, such as voltage and/or current, to deviate from acceptable operating margins or tolerances. In some cases, a high enough contact resistance may cause a bond pad to be out of specification and result in an entire die being unusable.

Additionally, or alternatively, a chemically-induced corrosion of a bond pad may cause poor contact between the bond pad and a bond ball. In some cases, the poor contact may cause poor signal conduction between the bond pad and the bond ball, thereby reducing an operating efficiency of the die. In some cases, the poor contact may cause detachment of the bond pad and the bond ball, thereby shortening a lifetime of the die.

Thus, post fabrication and assembly yields may be impacted by bond pad condition. Currently, there is no test system that is designed for pad corrosion monitoring and detection.

Some implementations described herein provide a corrosion test system for monitoring for and detecting corrosion (e.g., chemically-induced corrosion) of one or more bond pads (e.g., die pads) of a die integrated on a wafer. The corrosion test system may perform a corrosion test on each die of a wafer prior to wire bonding and dicing in order to assess whether or not corrosion is present at the bond pads of each die.

The corrosion test system may include one or more test structures in a wafer scribe region of the wafer. For example, the wafer scribe region may correspond to one or more scribe lines of the wafer. Thus, the test structures arranged in the wafer scribe region do not take up valuable die area of the dies, and, subsequent to the corrosion test, are discarded during dicing of the wafer. The one or more test structures may include a reference test structure (e.g., an unexposed test structure) and an evaluated test structure (e.g., an exposed test structure). The reference test structure may be arranged in an interior of the wafer such that the reference test structure is not exposed to an environment. In contrast, the evaluated test structure may be arranged at an exterior of the wafer such that the evaluated test structure is exposed to the environment, and may be susceptible to corrosion (e.g., a chemically-induced corrosion).

The corrosion test system may measure a reference value (e.g., a voltage drop or a resistance) associated with the reference test structure and a test value (e.g., a voltage drop or a resistance) associated with the evaluated test structure. Additionally, the corrosion test system may evaluate a comparison value of the reference value and the test value to determine whether or not corrosion is present at the evaluated test structure, which may also indicate whether or not corrosion is present at the bond pads of the die. The corrosion test system may evaluate the comparison value by performing a division operation of the reference value and the test value, where the comparison value corresponds to the quotient (i.e., a ratio) of the two values, or a subtraction operation of the reference value and the test value, where the comparison value corresponds to the difference of the two values.

When a metal corrodes, an electrical resistance of the metal may increase due to a reduction in a thickness of the metal and/or a reduction in surface area of a cross-section of the metal. In some examples, an increase in electrical resistance may be detected as a change in voltage (e.g., a change in voltage drop) across the metal. By measuring a change in electrical resistance of the metal over time, a rate of metal dissolution and a corrosion rate may be determined. As an extension of these principles, when the evaluated test structure corrodes, an electrical resistance of the evaluated test structure may increase. The corrosion test system may detect an increase in the electrical resistance of the evaluated test structure based on a comparison with the electrical resistance of the reference test structure, which may be protected from corrosion.

Accordingly, the corrosion test system may determine an amount of corrosion present (e.g., whether or not corrosion is present) at the evaluated test structure and at the bond pads of the die based on the comparison value of the reference value and the test value satisfying a threshold. In some implementations, the corrosion test system may determine whether or not corrosion is sufficiently high (e.g., based on satisfying a threshold) to fail the corrosion test. When a die region fails the corrosion test, the corrosion test system may flag the die region (or corresponding die) for disposal and dispose of the die after the wafer is diced into dies. Alternatively, when a die region fails the corrosion test, the corrosion test system may repair or reapply the bond pads of the die to eliminate the corrosion. In some implementations, the comparison value may be indicative of an amount of a corrosion that is present at the evaluated test structure and/or the bond pads of the die. In some implementations, the corrosion test system may determine how much corrosion is present at the evaluated test structure and/or the bond pads of the die (e.g., no corrosion, an acceptable amount of corrosion, or an unacceptable amount of corrosion). In some implementations, the corrosion test system may determine how much corrosion is present at the evaluated test structure and/or the bond pads of the die based on one or more thresholds. In some implementations, the comparison value may be proportional to the amount of corrosion that is present at the evaluated test structure and/or the bond pads of the die. Thus, the corrosion test system may determine how much corrosion is present at the evaluated test structure and/or the bond pads of the die based on a correlation between the comparison value and the amount of corrosion. For example, the corrosion test system may determine how much corrosion is present at the evaluated test structure and/or the bond pads of the die based on a lookup table. In some implementations, the corrosion test system may determine a lifetime of the bond pads of the die based on the comparison value. For example, by measuring a change in the comparison value over time, a rate of metal dissolution and a corrosion rate may be determined. The corrosion test system may determine a lifetime of the bond pads of the die based on the rate of metal dissolution and/or the corrosion rate.

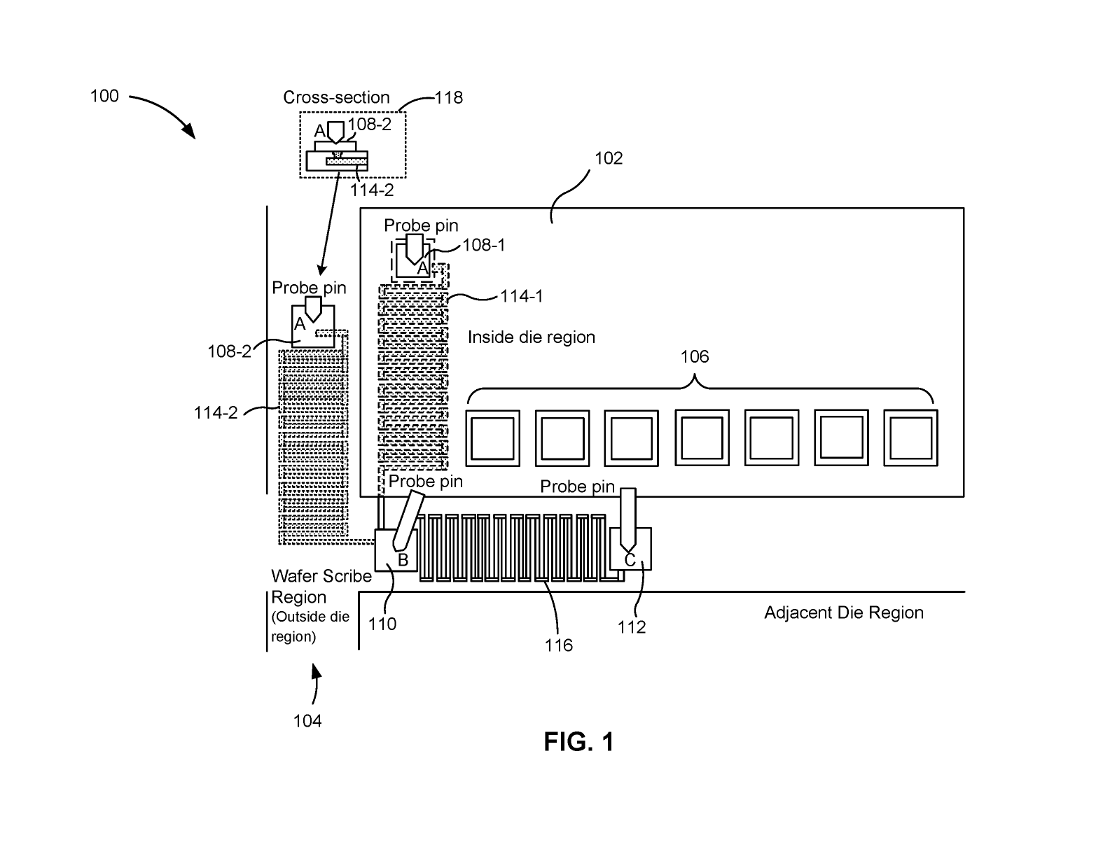

FIG. 1 shows a wafer 100 according to one or more implementations. The wafer 100 may be part of a corrosion test system described elsewhere herein. The wafer 100 may include one or more die regions 102 (e.g., one or more dies) separated by a wafer scribe region 104 arranged outside of the one or more die regions 102. The wafer scribe region 104 may include one or more wafer scribe lines along which dies are separated from the wafer 100 during a dicing process. Here, die region 102 may be evaluated for corrosion according to a corrosion test. The die region 102 may include one or more bond pads 106 that are used for operating a die associated with the die region 102.

The wafer 100 may include test structures, including a first test pad 108, a second test pad 110, a third test pad 112, an unexposed trace 114 (e.g., a reference test structure), and an exposed trace 116 (e.g., an evaluated test structure). The test structures may be made out of a same conductive material used for the bond pads 106, such as aluminum. The first test pad 108 may correspond to first test pad 108-1 or first test pad 108-2. The unexposed trace 114 may correspond to unexposed trace 114-1 or unexposed trace 114-2. In some implementations, the first test pad 108 and the unexposed trace 114 may be arranged in the die region 102, as represented by the first test pad 108-1 and the unexposed trace 114-1. Alternatively, in order to not occupy any area within the die region 102, the first test pad 108 and the unexposed trace 114 may be arranged in the wafer scribe region 104, as represented by the first test pad 108-2 and the unexposed trace 114-2. The second test pad 110 and the third test pad 112, along with the exposed trace 116, may be arranged in the wafer scribe region 104.

The test structures may be connected to form a voltage divider. Here, the first test pad 108, the second test pad 110, the third test pad 112, the unexposed trace 114, and the exposed trace 116 may be arranged in a voltage divider configuration. For example, the unexposed trace 114 may be coupled to the first test pad 108 and the second test pad 110 to form a first leg of the voltage divider. The exposed trace 116 may be coupled to the second test pad 110 and the third test pad 112 to form a second leg of the voltage divider.

The unexposed trace 114 may be arranged inside the wafer 100. Thus, the unexposed trace 114 may be routed through one or more inner layers of the wafer 100 such that the unexposed trace 114 is not exposed to an environment. In other words, the unexposed trace 114 may be protected from corrosion (e.g., the unexposed trace 114 may not be exposed to corrosive chemicals, metals, or other materials). In some implementations, the unexposed trace 114 may be covered by a passivation layer. In contrast, the exposed trace 116 may be arranged on the wafer 100 such that the exposed trace 116 is exposed to the environment. In some implementations, the exposed trace 116 may be routed on or through an outer layer of the wafer 100. Thus, the exposed trace 116 may be unprotected from corrosion (e.g., the exposed trace 116 may be exposed to corrosive chemicals, metals, or other materials). The exposed trace 116 may be configured to mimic or replicate conditions present at the bond pads 106. Thus, if the corrosion test system detects corrosion at the exposed trace 116, the corrosion test system may infer that corrosion is also present at the bond pads 106.

When a power supply is applied across the voltage divider, the unexposed trace 114 may be configured to conduct a current and induce a first voltage drop representative of a reference value, and the exposed trace 116 may be configured to conduct the current and induce a second voltage drop representative of a test value. The reference value may be the first voltage drop (e.g., V1) or a resistance (e.g., Z1) of the unexposed trace 114. The test value may be second voltage drop (e.g., V2) or a resistance (e.g., Z2) of the exposed trace 116.

In some implementations, the unexposed trace 114 and the exposed trace 116 may be designed to have substantially equal resistances when corrosion is absent from both the unexposed trace 114 and the exposed trace 116. For example, the unexposed trace 114 and the exposed trace 116 may have substantially similar dimensions (e.g., a same length and width). In some implementations, the unexposed trace 114 and the exposed trace 116 may be designed to have a predetermined (or expected) ratio of resistances (e.g., 1:1, 1:2, etc.) when corrosion is absent from both the unexposed trace 114 and the exposed trace 116. For example, a width of the exposed trace 116 may be thicker than a width of the unexposed trace 114, or vice versa. By increasing the width of the exposed trace 116, a surface area of the exposed trace 116 may be increased in order to provide more surface area for corrosion to occur, thereby increasing a likelihood of detecting corrosion when corrosion is present at the exposed trace 116 and/or the bond pads 106. In other words, increasing the width of the exposed trace 116 may provide a more accurate representation of a condition at the bond pads 106.

In some implementations, the unexposed trace 114 may be a first meandering conductive structure, and the exposed trace 116 may be a second meandering conductive structure. For example, both the unexposed trace 114 and the exposed trace 116 may alternate or zig-zag back and forth, side-to-side, as the traces extend between respective test pads to increase a conductive path length to ensure that a measurable electrical resistance is provided.

Cross-section view 118 shows a cross-section of the first test pad 108 and the unexposed trace 114. The first test pad 108 may be arranged on the wafer 100. The unexposed trace 114 may be connected to a bottom of the first test pad 108 by a conductive via. Similarly, the unexposed trace 114 may be connected to a bottom of the second test pad 110 by a conductive via. Thus, the unexposed trace 114 may be routed through an interior of the wafer 100 such that the unexposed trace 114 is not exposed to the environment.

A comparison value (e.g., a ratio or difference) of the reference value and the test value may be correlated with an amount of corrosion (e.g., chemically-induced corrosion) at the exposed trace 116. For example, the comparison value may be indicative of whether or not corrosion is present at the exposed trace 116. Accordingly, the comparison value of the reference value and the test value may be indicative of an amount of corrosion at the bond pads 106. For example, the comparison value may be indicative of whether or not corrosion is present at the bond pads 106.

The comparison value may have an expected value or may be expected to be within an expected range when corrosion is absent from both the unexposed trace 114 and the exposed trace 116 (e.g., based on expected resistances of the unexposed trace 114 and the exposed trace 116). However, when corrosion is present at the exposed trace 116, the comparison value may change based on an increase of resistance of the exposed trace 116 caused by the corrosion. Thus, the comparison value may deviate from the expected range when corrosion or an unacceptable amount of corrosion is present at the exposed trace 116, which may be indicative of corrosion or an unacceptable amount of corrosion being present at the bond pads 106.

For measuring the comparison value, a first test probe may be applied to the first test pad 108 for measuring a first voltage A at the first test pad 108, a second test probe may be applied to the second test pad 110 for measuring a second voltage B at the second test pad 110, and a third test probe may be applied to the third test pad 112 for measuring a third voltage C at the third test pad 112. The reference value may be calculated based on a difference between the first voltage A and the second voltage B. The test value may be calculated based on a difference between the second voltage B and the third voltage C.

For example, a power supply may be configured to induce the current, the test probes may be applied to the test pads to measure the reference value and the test value, and a processing circuit may be configured to calculate a measurement value based on the reference value and the test value. The measurement value may be correlated with a resistance of the exposed trace 116. For example, the measurement value may be the ratio or the difference of the reference value and the test value. Alternatively, the measurement value may be a measured resistance of the exposed trace 116. The processing circuit may detect a corrosion at the exposed trace 116, and thereby at the bond pads 106, based on the measurement value satisfying a threshold.

After the corrosion test, the wafer 100 may be separated into individual dies (e.g., semiconductor dies). The wafer serves as a substrate for each die, with multiple layers, including inner layers in which conductive layers or traces and non-conductive layers are provided. One or more integrated circuits are located within each die region to carry out one or more operations of the die. Thus, a die, separated from the wafer 100, includes a die region 102 comprising one or more bond pads 106 coupled to one or more integrated circuits located within the die region 102; and a wafer scribe region 104 arranged outside of the die region 102, the wafer scribe region 104 defining outer edges of the die. In some examples, part of the wafer scribe region 104 may remain. In addition, the die includes a test pad 108-1 arranged on a die surface of the die region 102; and an unexposed trace 114-1 coupled to the test pad 108-1 by a conductive structure, such as a conductive via, that extends from the test pad 108-1, into the semiconductor die, to the unexposed trace 114-1. The unexposed trace 114-1 is arranged inside the semiconductor die (e.g., within an interior of the semiconductor die, routed through the inner layers of the substrate or wafer). Additionally, the unexposed trace 114-1 extends laterally from the conductive structure to an outer edge of the semiconductor die defined by the wafer scribe region 114-1. A distal end of the unexposed trace 114-1 may be visible from the outer edge.

As indicated above, FIG. 1 is provided as an example. Other examples may differ from what is described with respect to FIG. 1.

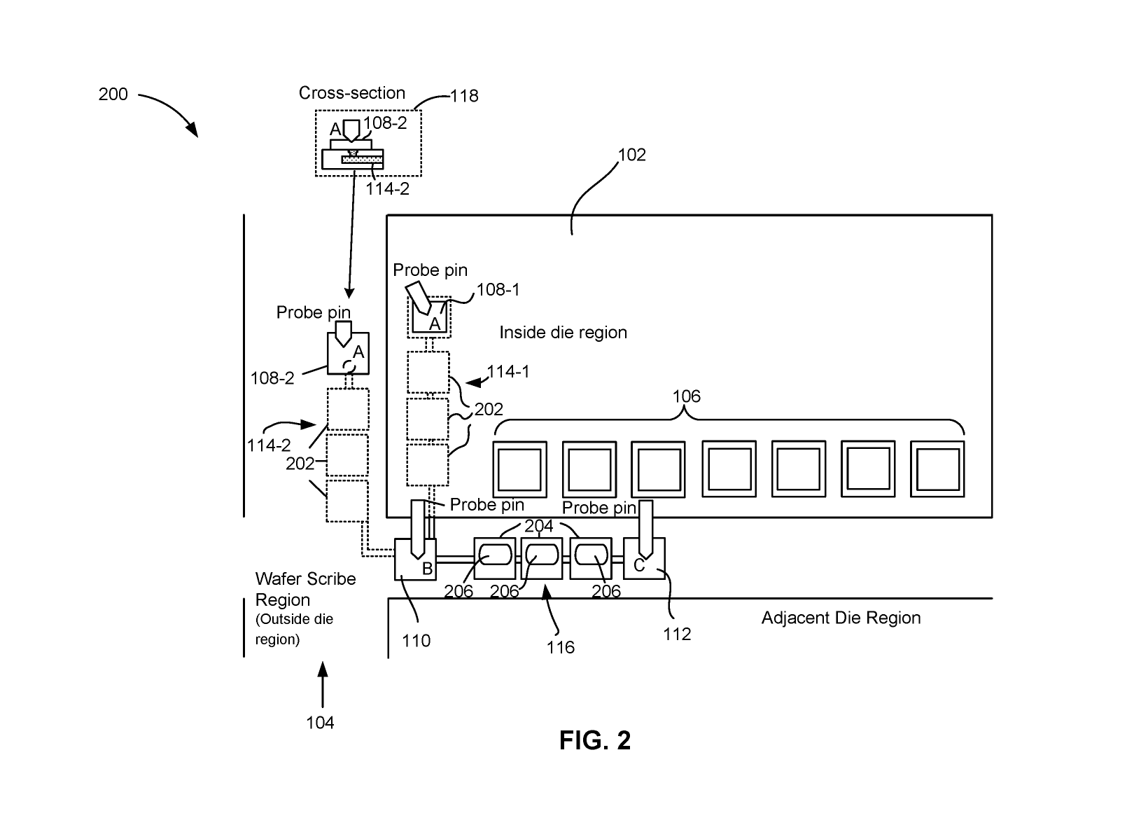

FIG. 2 shows a wafer 200 according to one or more implementations. The wafer 200 may be part of a corrosion test system described elsewhere herein. The wafer 200 may be similar to the wafer 100 described in connection with FIG. 1, except the unexposed trace 114 and the exposed trace 116 may include respective test pads arranged along straight conductive paths.

For example, the unexposed trace 114 may include a plurality of reference test pads 202 arranged inside the wafer 200. The exposed trace 116 may include a plurality of exposed test pads 204 arranged on the wafer 200. The test pads 202 and 204 may be used to mimic or replicate the bond pads 106 in surface area.

In some implementations, bond balls 206 may be arranged on the exposed trace 116. Here, each bond ball 206 is arranged on a respective exposed test pad of the plurality of exposed test pads 204. The bond balls 206 may be used to test whether galvanic corrosion occurs on the plurality of exposed test pads 204, which may indicate whether galvanic corrosion would occur at the bond pads 106.

A comparison value of the reference value and the test value may be correlated with an amount of corrosion (e.g., chemically-induced corrosion) at the exposed trace 116. For example, the comparison value may be indicative of whether or not corrosion is present at the exposed trace 116. Accordingly, the comparison value of the reference value and the test value may be indicative of an amount of corrosion at the bond pads 106. For example, the comparison value may be indicative of whether or not corrosion is present at the bond pads 106.

As indicated above, FIG. 2 is provided as an example. Other examples may differ from what is described with respect to FIG. 2.

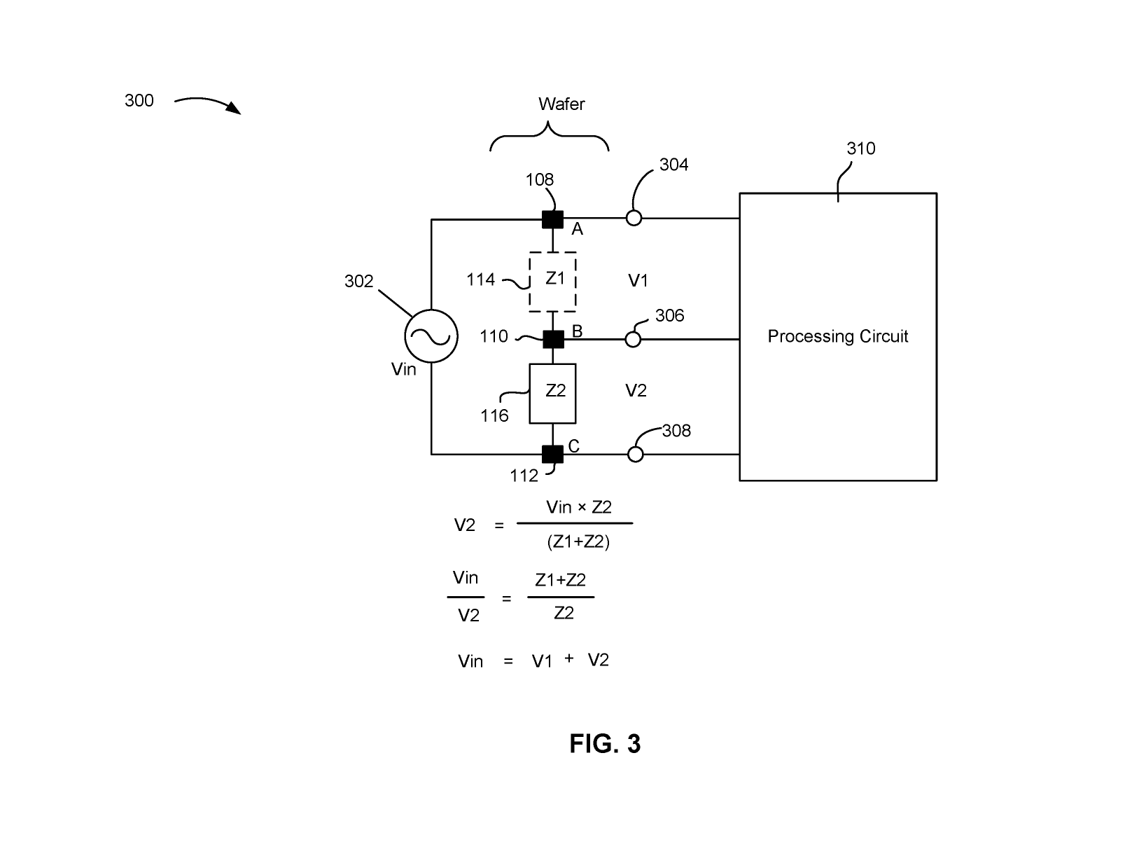

FIG. 3 shows a schematic diagram of a corrosion test system 300 according to one or more implementations. The corrosion test system 300 may include a wafer (e.g., wafer 100 or wafer 200) as described in connection with FIGS. 1 and 2. Here, the test structures of the wafer are shown, including the first test pad 108, the second test pad 110, the third test pad 112, the unexposed trace 114, and the exposed trace 116 arranged in a voltage divider configuration. The corrosion test system 300 may further include a power supply 302, plurality of test probes 304, 306, and 308, and a processing circuit 310.

The power supply 302 may be configured to induce a current through the voltage divider (e.g., through the unexposed trace 114 and the exposed trace 116). For example, the power supply 302 may be a voltage source that provides an input voltage Vin across the voltage divider. The unexposed trace 114 may have a first electrical resistance Z1. The exposed trace 116 may have a second electrical resistance Z2 that depends on whether or not corrosion is present at the exposed trace 116. In some implementations, the second electrical resistance Z2 may be proportional to an amount of corrosion at the exposed trace 116. The second electrical resistance Z2 may be indicative of whether or not corrosion is present at the bond pads 106. In contrast, the unexposed trace 114 may have a first electrical resistance Z1 that is independent of whether or not corrosion is present at the exposed trace 116 and/or the bond pads 106.

The plurality of test probes 304, 306, and 308 may include a first test probe 304 applied to the first test pad 108 for measuring a first voltage A, a second test probe 306 applied to the second test pad 110 for measuring a second voltage B, and a third test probe 308 applied to the third test pad 112 for measuring a third voltage C.

The processing circuit 310 may include one or more processors and/or processing circuitry (e.g., logic circuits, including logic gates and/or gate arrays, analog-to-digital converters, etc.) for evaluating corrosion of the exposed trace 116. For example, the processing circuit 310 may calculate a reference value based on a difference between the first voltage A and the second voltage B. The processing circuit 310 may also calculate a test value based on a difference between the second voltage B and the third voltage C. The processing circuit 310 may calculate a measurement value based on the reference value and the test value. For example, the measurement value may be a ratio of (A-B) and (B-C). Alternatively, the measurement value may be a difference between (A-B) and (B-C).

The processing circuit 310 may compare the measurement value to one or more thresholds for determining an amount of corrosion at the exposed trace 116, and thereby for determining an amount of corrosion at the bond pads 106 described in connection with FIGS. 1 and 2. Thus, the processing circuit 310 may detect corrosion at the exposed trace 116 based on the measurement value satisfying one or more thresholds. In addition, the processing circuit 310 may indicate that corrosion at the one or more bond pads 106 is present based on detecting the corrosion at the exposed trace 116. In some implementations, the processing circuit 310 may be part of a controller or may be communicatively coupled to the controller. Based on detecting the corrosion at the exposed trace 116, the processing circuit 310 may indicate that a die region (e.g., a die) has failed a corrosion test and is faulty. Thus, the processing circuit 310 may flag the die region for disposal such that the die corresponding to the (faulty) die region is disposed of after the wafer is diced into dies. Alternatively, failing the corrosion test may cause the processing circuit 310 or the controller to perform additional tests on the bond pads 106 and/or take corrective actions to repair the bond pads 106.

As indicated above, FIG. 3 is provided as an example. Other examples may differ from what is described with respect to FIG. 3.

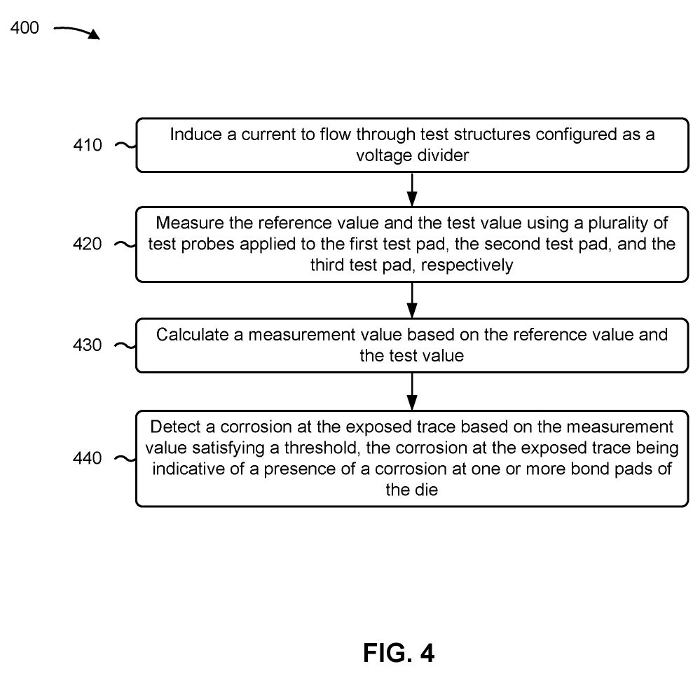

FIG. 4 is a flowchart of an example method 400 associated with in-situ test structure at a wafer scribe line for pad corrosion monitoring and testing. The method 400 may be a method of performing a corrosion test on a die integrated in a wafer. In some implementations, a corrosion test system (e.g., the corrosion test system 300) may perform or may be configured to perform the method 400. The method may be performed by the corrosion test system to evaluate bond pad corrosion (e.g., chemically-induced corrosion) of bond pads arranged within a die region of a wafer. In some implementations, another device or a group of devices separate from or including the corrosion test system (e.g., a controller) may perform or may be configured to perform the method 400. Additionally, or alternatively, one or more components of the corrosion test system (e.g., power supply 302, test probes 304, 306, and 308, and processing circuit 310) may perform or may be configured to perform the method 400. Thus, means for performing the method 400 may include the corrosion test system and/or one or more components of the corrosion test system. Additionally, or alternatively, a non-transitory computer-readable medium may store one or more instructions that, when executed by the corrosion test system, cause the corrosion test system to perform the method 400.

As shown in FIG. 4, the method 400 may include inducing a current to flow through test structures configured as a voltage divider (block 410). The voltage divider may include a first test pad formed on the wafer; a second test pad formed on the wafer; a third test pad formed on the wafer; an unexposed trace formed inside the wafer, wherein the unexposed trace is coupled to the first test pad and the second test pad, and wherein the unexposed trace is configured to conduct a current and induce a first voltage drop representative of a reference value; and an exposed trace formed on the wafer, outside of the die, wherein the exposed trace is coupled to the second test pad and the third test pad, and wherein the exposed trace is configured to conduct the current and induce a second voltage drop representative of a test value

As further shown in FIG. 4, the method 400 may include measuring the reference value and the test value using a plurality of test probes applied to the first test pad, the second test pad, and the third test pad, respectively (block 420).

As further shown in FIG. 4, the method 400 may include calculating a measurement value based on the reference value and the test value (block 430).

As further shown in FIG. 4, the method 400 may include detecting a corrosion at the exposed trace based on the measurement value satisfying a threshold, the corrosion at the exposed trace being indicative of a presence of a corrosion at one or more bond pads of the die (block 440).

The method 400 may include additional aspects, such as any single aspect or any combination of aspects described below and/or described in connection with one or more other methods or operations described elsewhere herein.

In a first aspect, the measurement value is a ratio or a difference of the reference value and the test value (e.g., a comparison value), and the ratio or the difference of the reference value and the test value is correlated with an amount of the corrosion at the exposed trace.

The method 400 may provide real-time bond pad resistance measurements and an accelerated corrosion testing method on a testable wafer platform to quantify a wafer’s (or a die’s) associated bond pad lifetime. The method 400 may be applied with an in-situ wafer form probing test. The

Although FIG. 4 shows example blocks of a method 400, in some implementations, the method 400 may include additional blocks, fewer blocks, different blocks, or differently arranged blocks than those depicted in FIG. 4. Additionally, or alternatively, two or more of the blocks of the method 400 may be performed in parallel. The method 400 is an example of one method that may be performed by one or more devices described herein. These one or more devices may perform or may be configured to perform one or more other methods based on operations described herein.

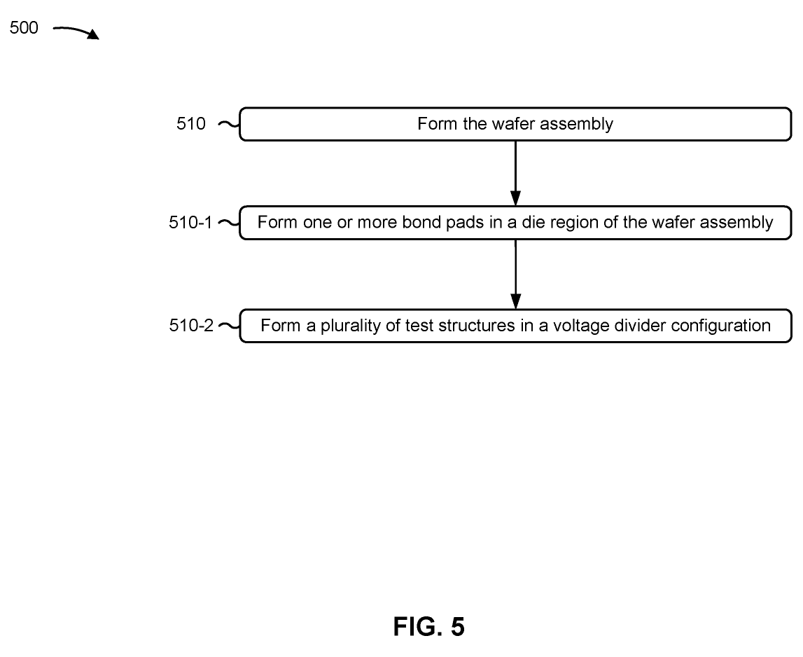

FIG. 5 is a flowchart of an example method 500 of manufacturing a wafer assembly (e.g., a wafer). In some implementations, the method 500 may be associated with manufacturing plurality of dies from the wafer assembly. The wafer assembly may have a measurable test pad design for aluminum pad corrosion behavior monitoring and evaluation. In some implementations, one or more process blocks of FIG. 5 may be performed by various semiconductor manufacturing equipment.

As shown in FIG. 5, the method 500 may include forming the wafer assembly (block 510). As further shown in FIG. 5, forming the wafer assembly may include forming one or more bond pads in a die region of the wafer assembly (block 510-1). Additionally, as further shown in FIG. 5, forming the wafer assembly may include forming a plurality of test structures in a voltage divider configuration (block 510-2). The plurality of test structures may include a first test pad formed on the wafer assembly; a second test pad formed on the wafer assembly; a third test pad formed on the wafer assembly; an unexposed trace formed inside the wafer assembly, wherein the unexposed trace, corresponding to a first leg of the voltage divider configuration, is coupled to the first test pad and the second test pad; and an exposed trace formed on the wafer assembly, outside of the die region, wherein the exposed trace, corresponding to a second leg of the voltage divider configuration, is coupled to the second test pad and the third test pad, and wherein a comparison value of a resistance of the unexposed trace and a resistance of the exposed trace is associated with an amount of corrosion at the one or more bond pads.

The method 500 may include additional aspects, such as any single aspect or any combination of aspects described below and/or in connection with one or more other methods described elsewhere herein. Additionally, aspects may include evaluating bond pad corrosion of the bond pads in the die region.

In a first aspect, the method 500 includes inducing, by a power supply, a current to flow through the unexposed trace and the exposed trace in order to induce a first voltage across the unexposed trace and a second voltage across the exposed trace, measuring, by a processing circuit, the first voltage and the second voltage using a plurality of test probes applied to the first test pad, the second test pad, and the third test pad, respectively, calculating, by the processing circuit, a measurement value based on the first voltage and the second voltage, and detecting, by the processing circuit, corrosion at the exposed trace based on the measurement value satisfying a threshold, wherein the corrosion at the exposed trace is indicative of a presence of corrosion at one or more bond pads in the die region.

In a second aspect, alone or in combination with the first aspect, the unexposed trace is arranged in the die region, wherein the exposed trace is arranged in a wafer scribe region of the wafer assembly, wherein the first test pad is arranged in the die region, and wherein the second test pad and the third test pad are arranged in the wafer scribe region.

In a third aspect, alone or in combination with one or more of the first and second aspects, the unexposed trace and the exposed trace are arranged in a wafer scribe region of the wafer assembly, and the first test pad, the second test pad, and the third test pad are arranged in the wafer scribe region.

In some implementations, the method 400 may be incorporated into the method 500 such that the method 500 includes the method 400.

Although FIG. 5 shows example blocks of the method 500, in some implementations, the method 500 may include additional blocks, fewer blocks, different blocks, or differently arranged blocks than those depicted in FIG. 5. In some implementations, the method 500 may include forming the wafer 100 or wafer 200, an integrated assembly that includes wafer 100 or wafer 200, any part described herein of wafer 100 or wafer 200, and/or any part described herein of an integrated assembly that includes wafer 100 or wafer 200. For example, the method 500 may include forming one or more dies from wafer 100 or wafer 200.

In some implementations, a wafer includes a die region comprising one or more bond pads; a wafer scribe region arranged outside of the die region; and a voltage divider comprising: a first test pad; a second test pad; a third test pad; an unexposed trace coupled to the first test pad and the second test pad, wherein the unexposed trace is arranged inside the wafer, and wherein the unexposed trace is configured to conduct a current and induce a first voltage drop representative of a reference value; and an exposed trace coupled to the second test pad and the third test pad, wherein the exposed trace is arranged on the wafer, in the wafer scribe region, and wherein the exposed trace is configured to conduct the current and induce a second voltage drop representative of a test value, wherein a comparison value of the reference value and the test value is indicative of an amount of a chemically-induced corrosion at the one or more bond pads.

In some implementations, a corrosion test system includes a wafer, comprising: a die region comprising one or more bond pads; a wafer scribe region arranged outside of the die region; and a voltage divider comprising: a first test pad; a second test pad; a third test pad; an unexposed trace coupled to the first test pad and the second test pad, wherein the unexposed trace is arranged inside the wafer, and wherein the unexposed trace is configured to conduct a current and induce a first voltage drop representative of a reference value; and an exposed trace coupled to the second test pad and the third test pad, wherein the exposed trace is arranged on the wafer, in the wafer scribe region, and wherein the exposed trace is configured to conduct the current and induce a second voltage drop representative of a test value, wherein a comparison value of the reference value and the test value is indicative of an amount of a chemically-induced corrosion at the one or more bond pads; a power supply configured to induce the current; a plurality of test probes configured to measure the reference value and the test value; and a processing circuit configured to calculate a measurement value based on the reference value and the test value, and detect a chemically-induced corrosion at the exposed trace based on the measurement value satisfying a threshold.

In some implementations, a method of performing a corrosion test on a die integrated in a wafer includes inducing, by a power supply, a current to flow through test structures configured as a voltage divider, wherein the voltage divider comprises: a first test pad formed on the wafer; a second test pad formed on the wafer; a third test pad formed on the wafer; an unexposed trace formed inside the wafer, wherein the unexposed trace is coupled to the first test pad and the second test pad, and wherein the unexposed trace is configured to conduct a current and induce a first voltage drop representative of a reference value; and an exposed trace formed on the wafer, outside of the die, wherein the exposed trace is coupled to the second test pad and the third test pad, and wherein the exposed trace is configured to conduct the current and induce a second voltage drop representative of a test value, measuring, by a processing circuit, the reference value and the test value using a plurality of test probes applied to the first test pad, the second test pad, and the third test pad, respectively; calculating, by the processing circuit, a measurement value based on the reference value and the test value; and detecting, by the processing circuit, a corrosion at the exposed trace based on the measurement value satisfying a threshold, the corrosion at the exposed trace being indicative of a presence of a corrosion at one or more bond pads of the die.

In some implementations, a method of manufacturing a wafer assembly includes forming the wafer assembly, including: forming one or more bond pads in a die region; and forming a plurality of test structures in a voltage divider configuration, the plurality of test structures including: a first test pad formed on the wafer assembly; a second test pad formed on the wafer assembly; a third test pad formed on the wafer assembly; an unexposed trace formed inside the wafer assembly, wherein the unexposed trace, corresponding to a first leg of the voltage divider configuration, is coupled to the first test pad and the second test pad; and an exposed trace formed on the wafer assembly, outside of the die region, wherein the exposed trace, corresponding to a second leg of the voltage divider configuration, is coupled to the second test pad and the third test pad, and wherein a comparison value of a resistance of the unexposed trace and a resistance of the exposed trace is associated with an amount of corrosion at the one or more bond pads.

In some implementations, a semiconductor die includes a die region comprising one or more bond pads coupled to one or more integrated circuits located within the die region; a wafer scribe region arranged outside of the die region, the wafer scribe region defining outer edges of the semiconductor die; a test pad arranged on a die surface of the die region; and an unexposed trace coupled to the test pad by a conductive structure that extends from the test pad, into the semiconductor die, to the unexposed trace, wherein the unexposed trace is arranged inside the semiconductor die, and wherein the unexposed trace extends laterally from the conductive structure to an outer edge of the semiconductor die defined by the wafer scribe region.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element’s relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like. All ranges described herein are inclusive of numbers at the ends of those ranges, unless specifically indicated otherwise.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a + b, a + c, b + c, and a + b + c, as well as any combination with multiples of the same element (e.g., a + a, a + a + a, a + a + b, a + a + c, a + b + b, a + c + c, b + b, b + b + b, b + b + c, c + c, and c + c + c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A wafer, comprising:
a die region comprising one or more bond pads;
a wafer scribe region arranged outside of the die region; and
a voltage divider comprising:
a first test pad;
a second test pad;
a third test pad;
an unexposed trace coupled to the first test pad and the second test pad, wherein the unexposed trace is arranged inside the wafer, and wherein the unexposed trace is configured to conduct a current and induce a first voltage drop representative of a reference value; and
an exposed trace coupled to the second test pad and the third test pad, wherein the exposed trace is arranged on the wafer, in the wafer scribe region, and wherein the exposed trace is configured to conduct the current and induce a second voltage drop representative of a test value,
wherein a comparison value of the reference value and the test value is indicative of an amount of a chemically-induced corrosion at the one or more bond pads.

2. The wafer of claim 1, wherein the unexposed trace is routed through one or more inner layers of the wafer and is not exposed to an environment, and
wherein the exposed trace is routed on or through an outer layer of the wafer and is exposed to the environment.

3. The wafer of claim 1, wherein the unexposed trace is not exposed to a corrosive chemical or a corrosive metal, and
wherein the exposed trace is exposed to the corrosive chemical or the corrosive metal.

4. The wafer of claim 1, wherein the unexposed trace is arranged in the die region,
wherein the first test pad is arranged in the die region, and
wherein the second test pad and the third test pad are arranged in the wafer scribe region.

5. The wafer of claim 1, wherein the unexposed trace is arranged in the wafer scribe region, and
wherein the first test pad, the second test pad, and the third test pad are arranged in the wafer scribe region.

6. The wafer of claim 1, wherein the unexposed trace is a first meandering conductive structure, and
wherein the exposed trace is a second meandering conductive structure.

7. The wafer of claim 1, wherein the unexposed trace includes a plurality of reference test pads arranged inside the wafer, and
wherein the exposed trace includes a plurality of exposed test pads arranged on the wafer.

8. The wafer of claim 7, further comprising:
a plurality of bond balls arranged on the exposed trace,
wherein each bond ball of the plurality of bond balls is arranged on a respective exposed test pad of the plurality of exposed test pads.

9. A corrosion test system, comprising:
a wafer, comprising:
a die region comprising one or more bond pads;
a wafer scribe region arranged outside of the die region; and
a voltage divider comprising:
a first test pad;
a second test pad;
a third test pad;
an unexposed trace coupled to the first test pad and the second test pad, wherein the unexposed trace is arranged inside the wafer, and wherein the unexposed trace is configured to conduct a current and induce a first voltage drop representative of a reference value; and
an exposed trace coupled to the second test pad and the third test pad, wherein the exposed trace is arranged on the wafer, in the wafer scribe region, and wherein the exposed trace is configured to conduct the current and induce a second voltage drop representative of a test value,
wherein a comparison value of the reference value and the test value is indicative of an amount of a chemically-induced corrosion at the one or more bond pads;
a power supply configured to induce the current;
a plurality of test probes configured to measure the reference value and the test value; and
a processing circuit configured to calculate a measurement value based on the reference value and the test value, and detect a chemically-induced corrosion at the exposed trace based on the measurement value satisfying a threshold.

10. The corrosion test system of claim 9, wherein the measurement value is a ratio or a difference of the reference value and the test value.

11. The corrosion test system of claim 9, wherein the measurement value is correlated with a resistance of the exposed trace.

12. The corrosion test system of claim 9, wherein the plurality of test probes include:
a first test probe applied to the first test pad for measuring a first voltage at the first test pad;
a second test probe applied to the second test pad for measuring a second voltage at the second test pad; and
a third test probe applied to the third test pad for measuring a third voltage at the third test pad.

13. The corrosion test system of claim 9, wherein the unexposed trace is not exposed to an environment, and
wherein the exposed trace is exposed to the environment.

14. The corrosion test system of claim 9, wherein the unexposed trace is arranged in the die region.

15. The corrosion test system of claim 9, wherein the unexposed trace is arranged in the wafer scribe region.

16. The corrosion test system of claim 9, wherein the unexposed trace is a first meandering conductive structure, and
wherein the exposed trace is a second meandering conductive structure.

17. The corrosion test system of claim 9, wherein the unexposed trace includes a plurality of reference test pads arranged inside the wafer, and
wherein the exposed trace includes a plurality of exposed test pads arranged on the wafer.

18. The corrosion test system of claim 17, further comprising:
a plurality of bond balls arranged on the exposed trace,
wherein each bond ball of the plurality of bond balls is arranged on a respective exposed test pad of the plurality of exposed test pads.

19. The corrosion test system of claim 9, wherein the processing circuit is configured to indicate that the chemically-induced corrosion at the one or more bond pads is present based on detecting the chemically-induced corrosion at the exposed trace.

20. A method of performing a corrosion test on a die integrated in a wafer, the method comprising:
inducing, by a power supply, a current to flow through test structures configured as a voltage divider, wherein the voltage divider comprises:
a first test pad formed on the wafer;
a second test pad formed on the wafer;
a third test pad formed on the wafer;
an unexposed trace formed inside the wafer, wherein the unexposed trace is coupled to the first test pad and the second test pad, and wherein the unexposed trace is configured to conduct a current and induce a first voltage drop representative of a reference value; and
an exposed trace formed on the wafer, outside of the die, wherein the exposed trace is coupled to the second test pad and the third test pad, and wherein the exposed trace is configured to conduct the current and induce a second voltage drop representative of a test value,
measuring, by a processing circuit, the reference value and the test value using a plurality of test probes applied to the first test pad, the second test pad, and the third test pad, respectively;
calculating, by the processing circuit, a measurement value based on the reference value and the test value; and
detecting, by the processing circuit, a corrosion at the exposed trace based on the measurement value satisfying a threshold, the corrosion at the exposed trace being indicative of a presence of a corrosion at one or more bond pads of the die.

21. The method of claim 20, wherein the measurement value is a comparison value of the reference value and the test value, and
wherein the comparison value of the reference value and the test value is correlated with an amount of the corrosion at the exposed trace.

22. A method of manufacturing a wafer assembly, the method comprising:
forming the wafer assembly, including:
forming one or more bond pads in a die region; and
forming a plurality of test structures in a voltage divider configuration, the plurality of test structures including:
a first test pad formed on the wafer assembly;
a second test pad formed on the wafer assembly;
a third test pad formed on the wafer assembly;
an unexposed trace formed inside the wafer assembly, wherein the unexposed trace, corresponding to a first leg of the voltage divider configuration, is coupled to the first test pad and the second test pad; and
an exposed trace formed on the wafer assembly, outside of the die region, wherein the exposed trace, corresponding to a second leg of the voltage divider configuration, is coupled to the second test pad and the third test pad, and
wherein a comparison value of a resistance of the unexposed trace and a resistance of the exposed trace is associated with an amount of corrosion at the one or more bond pads.

23. The method of claim 22, further comprising:
inducing, by a power supply, a current to flow through the unexposed trace and the exposed trace in order to induce a first voltage across the unexposed trace and a second voltage across the exposed trace;
measuring, by a processing circuit, the first voltage and the second voltage using a plurality of test probes applied to the first test pad, the second test pad, and the third test pad, respectively;
calculating, by the processing circuit, a measurement value based on the first voltage and the second voltage; and
detecting, by the processing circuit, corrosion at the exposed trace based on the measurement value satisfying a threshold, wherein the corrosion at the exposed trace is indicative of a presence of corrosion at one or more bond pads in the die region.

24. The method of claim 22, wherein the unexposed trace is arranged in the die region,
wherein the exposed trace is arranged in a wafer scribe region of the wafer assembly,
wherein the first test pad is arranged in the die region, and
wherein the second test pad and the third test pad are arranged in the wafer scribe region.

25. The method of claim 22, wherein the unexposed trace and the exposed trace are arranged in a wafer scribe region of the wafer assembly, and
wherein the first test pad, the second test pad, and the third test pad are arranged in the wafer scribe region.

26. A semiconductor die, comprising:
a die region comprising one or more bond pads coupled to one or more integrated circuits located within the die region;
a wafer scribe region arranged outside of the die region, the wafer scribe region defining outer edges of the semiconductor die;
a test pad arranged on a die surface of the die region; and
an unexposed trace coupled to the test pad by a conductive structure that extends from the test pad, into the semiconductor die, to the unexposed trace,
wherein the unexposed trace is arranged inside the semiconductor die, and
wherein the unexposed trace extends laterally from the conductive structure to an outer edge of the semiconductor die defined by the wafer scribe region.

27. The wafer of claim 26, wherein the unexposed trace is routed through one or more inner layers of the semiconductor die and is not exposed to an environment within the die region.

28. The wafer of claim 26, wherein the unexposed trace is a meandering conductive structure.

29. The wafer of claim 26, wherein the unexposed trace includes a plurality of reference test pads arranged inside the semiconductor die.
